(19) United States
(12) Patent Application Publication
(10) Pub. No.: US 2025/0183218 A1
(43) Pub. Date: Jun. 5, 2025

(54) ELECTRICAL CONNECTING MEMBER AND SEMICONDUCTOR DEVICE

(71) Applicant: SHINDENGEN ELECTRIC MANUFACTURING CO., LTD., Tokyo (JP)

(72) Inventor: Yuji MORINAGA, Saitama (JP)

(21) Appl. No.: 18/842,799

(22) PCT Filed: Mar. 27, 2023
(86) PCT No.: PCT/JP2023/012296

§ 371 Date: Aug. 30, 2024

(30) Foreign Application Priority Data
Mar. 31, 2022 (JP) 2022-061179

(51) Int. Cl. H01L 23/00

(52) U.S. Cl. CPC H01L 24/37; H01L 24/40; H01L 2224/37011; H01L 2224/37013; H01L 2224/40227; H01L 2224/40475

(57) ABSTRACT

An electrical connecting member has a plate shape and is configured for connecting an electrode of a semiconductor element that has the electrode and a wiring pattern. The electrical connecting member includes: a semiconductor connection region that is connected to the electrode of the semiconductor element via a conductive bonding material; a semiconductor non-connection region that is not connected to the electrode of the semiconductor element; and a wiring pattern connection region that is connected to the wiring pattern, wherein a plurality of protrusions are formed in the semiconductor connection region, and a first through hole is formed between two protrusions disposed adjacently to each other out of the plurality of protrusions.

### RELATED APPLICATIONS

The present application is a National Phase of International Application No. PCT/JP2023/012296 filed Mar. 27, 2023, which claims priority to Japanese Application No. 2022-061179, filed Mar. 31, 2022.

### TECHNICAL FIELD

The present invention relates to an electrical connecting member and a semiconductor device.

### BACKGROUND ART

With the advent of next-generation power semiconductors (GaN and the like), along with a demand for semiconductors that can perform a switching operation at a high speed in the order of several MHz from the conventional several hundred kHz and a request for increasing a turn on-off speed at a high speed of one digit or more, there has been a demand for ensuring operational stability and reliability by reducing a switching loss, a surge voltage and noises at the time of performing a circuit system operation.

In view of the above, conventionally, as an electrical connecting member that connects a semiconductor element and a wiring pattern to each other, an electrical connecting member having a plate shape capable of reducing inductance has been used. This electrical connecting member having a plate shape is a member that is connected with the semiconductor element via a conductive bonding material.

Patent literature 1 discloses a semiconductor device where, on an intermediate portion of a lower surface of an electrical connecting member between a first bonding portion and a second bonding portion, to suppress leakage and spreading of a conductive bonding material such as solder from between the first bonding portion and an upper electrode of the semiconductor element to the intermediate portion, an oxide film of metal is formed. According to the semiconductor device described in patent literature 1, reliability of the semiconductor device can be enhanced by suppressing leakage and spreading of the conductive bonding material to the electrical connecting member.

### CITATION LIST

### Patent Literature

Patent Literature 1: JP-A-2019-220653

### SUMMARY OF INVENTION

### Technical Problem

However, in the above-mentioned prior art, the semiconductor element and the electrical connecting member are connected with each other by applying the conductive bonding material to an entire surface of the semiconductor element by coating and by reflowing the conductive bonding material in a state where the electrical connecting member is disposed on the conductive bonding material. Accordingly, such a technique has a drawback that there may arise a situation where the semiconductor element and the electrical connecting member are bonded to each other in an inclined state so that a thickness of the conductive bonding material becomes non-uniform. Further, because of such a drawback, another drawback that the reliability of a manufactured semiconductor device is lowered arises.

The present invention has been made to overcome the above-mentioned drawbacks, and it is an object of the present invention to provide a semiconductor device where a thickness of a conductive bonding material minimally becomes non-uniform so that the lowering of the reliability of the semiconductor device can be suppressed.

### Solution to Problem

(1) An electrical connecting member according to the present invention is an electrical connecting member having a plate shape that is used for connecting an electrode of a semiconductor element having the electrode and a wiring pattern to each other. The electrical connecting member includes: a semiconductor connection region that is connected to the electrode of the semiconductor element via a conductive bonding material; a semiconductor non-connection region that is not connected to the electrode of the semiconductor element; and a wiring pattern connection region that is connected to the wiring pattern.

A plurality of protrusions are formed in the semiconductor connection region, and a first through hole is formed between two protrusions disposed adjacently to each other out of the plurality of protrusions.

(2) In the electrical connecting member according to the present invention, it is preferable that the semiconductor element be a semiconductor element that has a plurality of electrodes on one surface thereof, and the electrical connecting member be used for connecting the plurality of electrodes and the wiring pattern to each other.

(3) In the electrical connecting member according to the present invention, it is preferable that the semiconductor element be a semiconductor element that has plural kinds of electrodes on one surface thereof, and the electrical connecting member be used for connecting one kind of electrode out of the plural kinds of electrodes and the wiring pattern to each other.

(4) In the electrical connecting member according to the present invention, it is preferable that the one kind of electrode be divided into a plurality of individual electrodes, and the plurality of respective protrusions are formed in regions of the plurality of respective individual electrodes that correspond to the plurality of respective individual protrusions.

(5) In the electrical connecting member according to the present invention, it is preferable that an area (a plane area) of the first through hole be smaller than an area (a plane area) of the protrusion.

(6) In the electrical connecting member according to the present invention, it is preferable that the protrusion have a conical shape or pyramidal shape.

(7) In the electrical connecting member according to the present invention, it is preferable that a second through hole be formed in the semiconductor non-connection region.

(8) A semiconductor device according to the present invention includes: a semiconductor element that has an electrode; a wiring pattern; and an electrical connecting member having a plate shape that connects the electrode of the semiconductor element and the wiring pattern. In the semiconductor device, the electrical connecting member is the electrical connecting member according to the present invention.

### Advantageous Effects of the Invention

According to the electrical connecting member of the present invention, the plurality of protrusions are formed in the semiconductor connection region. As a result, it is possible to prevent the bonding between the semiconductor element and the electrical connecting member in a state where the semiconductor element and the electrical connecting member are bonded to each other in an inclined state and hence, a thickness of the conductive bonding material becomes uniform. The conductive bonding material is applied by coating to the position that corresponds to the position where the position where the plurality of protrusions are formed and hence, unnecessary applying of the conductive bonding material by coating can be suppressed. Further, according to the electrical connecting member of the present invention, the first through hole is formed between two protrusions disposed adjacently to each other and hence, the flow of the melted conductive bonding material is divided and hence, it is possible to easily control the flow of the melted conductive bonding material and hence, the wetting and the spreading of the conductive bonding material more than necessary can be suppressed. Because of these results, according to the electrical connecting member of the present invention, it is possible to suppress the lowering of the reliability of the manufactured semiconductor device and hence, the semiconductor device according to the present invention becomes a semiconductor device where the lowering of the reliability is suppressed.

### BRIEF DESCRIPTION OF DRAWINGS

FIG. 1 is a perspective view of an electrical connecting member 110 according to the present invention.

FIG. 2 is a plan view of a semiconductor element 102 which is an object to which the electrical connecting member 110 of the present invention is connected.

FIG. 3A to FIG. 3C are views illustrating a state where the electrical connecting member 110 according to the present invention is connected to an electrode 104 of the semiconductor element 102.

FIG. 4 is an equivalent circuit 126 of an electronic module 130 according to an embodiment.

FIG. 5A and FIG. 5B are views illustrating an electrode structure of the semiconductor element (a first semiconductor element 10, a second semiconductor element 20) used in the embodiment.

FIG. 6 is an enlarged perspective view of a main part of the electronic module 130 according to the embodiment.

FIG. 7 is an enlarged perspective view of a main part of an electronic module 132 according to a modification 1.

### MODE FOR CARRYING OUT THE INVENTION

Hereinafter, an electrical connecting member and a semiconductor device according to the present invention are described with reference to drawings. The respective drawings are schematical views and it is not always a case that these drawings strictly reflect actual sizes. Further, the respective embodiments described hereinafter are not intended to limit the inventions called for in Claims. Further, it is not always the case that all of various constitutional elements and the combination of these elements described in the respective embodiments are indispensable as means for solving the problems according to the present invention. Further, in the respective embodiments, with respect to the basic configurations and the constitutional elements (including constitutional elements that do not have completely the same shapes or the like) that have substantially the same configuration, technical features, functions or the like, the same symbols may be used throughout all embodiments, and the repeated description of these configurations and constitutional elements is omitted.

### [Electrical Connecting Member and Semiconductor Device]

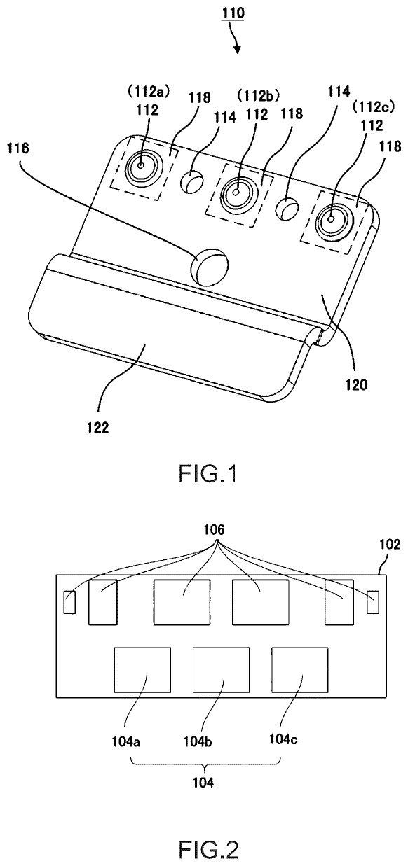

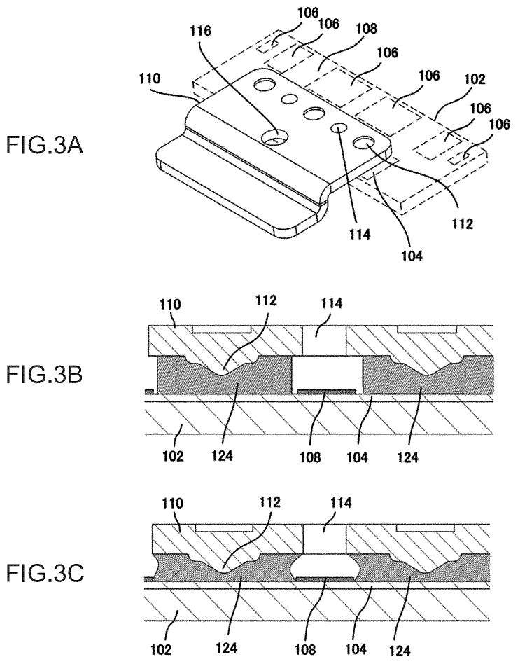

FIG. 1 is a perspective view of an electrical connecting member 110 according to the present invention. FIG. 2 is a plan view of the semiconductor element 102 which is an object to which the electrical connecting member 110 of the present invention is connected. FIG. 3A to FIG. 3C are views illustrating a state where the electrical connecting member 110 according to the present invention is connected to the electrode 104 of the semiconductor element 102. FIG. 3A is a perspective view illustrating such a state, and FIG. 3B and FIG. 3C are cross-sectional views of a main part illustrating such a state. FIG. 3B is the cross-sectional view of the main part before a joining step is performed, and FIG. 3C is the cross-sectional of the main part after the bonding step is performed.

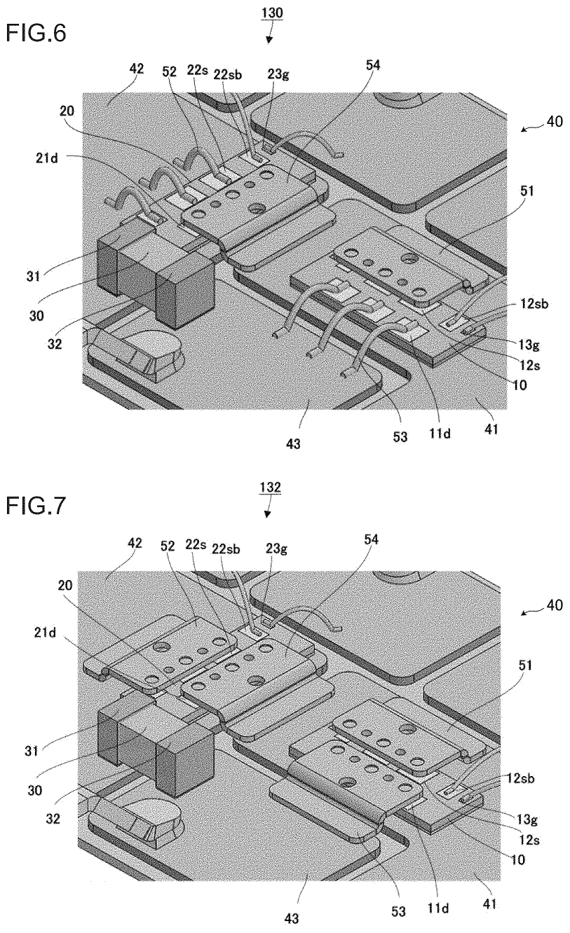

As illustrated in FIG. 1 to FIG. 3C, the electrical connecting member 110 according to the present invention is an electrical connecting member having a plate shape that is used for connecting an electrode 104 of the semiconductor element 102 having the electrode 104 and a wiring pattern (see a first wiring pattern 41 illustrated in FIG. 6 and described later). As illustrated in FIG. 1 and FIG. 2, the electrical connecting member 110 includes: a semiconductor connection region 118 to which the electrode 104 of the semiconductor element 102 is connected via a conductive bonding material 124; a semiconductor non-connection region 120 that is not connected to the electrode 104 of the semiconductor element 102; and a wiring pattern connection region 122 to which a wiring pattern is connected. A plurality of protrusions 112 are formed in the semiconductor connection region 118, and a first through hole 114 is formed in a region between two protrusions 112 disposed adjacently to each other among the plurality of protrusions 112 (a semiconductor non-contact region).

In the electrical connecting member 110 according to the present invention, as illustrated in FIG. 2, the semiconductor element 102 is a semiconductor element that includes a plurality of electrodes (individual electrodes 104a, 104b, 104c) on one surface thereof. The electrical connecting member 110 is used for connecting the plurality of electrodes (individual electrodes 104a, 104b, 104c) and the wiring pattern to each other.

In the electrical connecting member 110 according to the present invention, as illustrated in FIG. 2, the semiconductor element 102 is a semiconductor element that includes plural kinds of electrodes (the electrode 104 and another electrode 106) on one surface thereof. The electrical connecting member 110 is used for connecting one kind of electrode (the electrode 104) out of the plural kinds of electrodes (the electrode 104 and another electrode 106) and the wiring pattern to each other.

In the electrical connecting member 110 according to the present invention, one kind of electrode (electrode 104) in the semiconductor element 102 is, as illustrated in FIG. 2, divided into a plurality of individual electrodes 104a, 104b, 104c. The plurality of protrusions 112a, 112b, 112c (see FIG. 1) mounted on the electrical connecting element 110 are respectively formed on regions corresponding to the plurality of respective individual electrodes 104a, 104b, 104c (see FIG. 2 and FIG. 3A to FIG. 3C). In the present invention, one protrusion 112 may be formed in regions corresponding to the respective individual electrodes 104a, 104b, 104c (see FIG. 1), or the plurality of protrusion 112 may be formed in regions corresponding to the respective individual electrodes 104a, 104b, 104c.

In the electrical connecting member 110 according to the present invention, an area (a plane area) of the first through hole 114 is as illustrated in FIG. 1, smaller than an area (a plane area) of the protrusion 112. Further, in the electrical connecting member 110 according to the present invention, as illustrated in FIG. 1, the protrusion 112 has a conical shape. However, in the present invention, the protrusion 112 is not limited to a protrusion that has a conical shape, and may be a protrusion having a pyramidal shape, a circular columnar shape, a prismatic shape, a semispherical shape or other shapes.

Further, in the electrical connecting member 110 according to the present invention, as illustrated in FIG. 1 and FIG. 3A to FIG. 3C, a second through hole 116 is formed in the semiconductor non-connection region 120. The second through hole 116 is disposed on a vertical line extending from the protrusion 112 at the center (the protrusion 112b) to the wiring pattern connection region 122.

In the electrical connecting member 110 according to the present invention, as illustrated in FIG. 3A, a protective insulation layer 108 is formed in the entirety or a portion of the semiconductor non-connection region 120. As the protective insulation layer 108, a resist layer, a metal oxide layer or the like can be used.

As illustrated in FIG. 3A, the semiconductor device according to the present invention is a semiconductor device that includes; the semiconductor element 102 having the electrode 104; the wiring pattern (not illustrated in the drawing); and the electrical connecting member 110 having a plate shape that connects the electrode 104 of the semiconductor element 102 and the wiring pattern. In FIG. 3A, symbol 106 indicates other electrodes.

The connection of the electrical connecting member 110 to the semiconductor element 102 is performed as follows. That is, the conductive bonding material 124 is applied to the electrode 104 of the semiconductor element 102 by coating and, thereafter, the electrical connecting member 110 is mounted on the semiconductor element 102 in a state where the protrusion 112 (protrusions 112a, 112b, 112c) (see FIG. 1) of the electrical connecting member 110 face the electrode 104 (individual electrodes 104a, 104b, 104c) (see FIG. 2). Then, the conductive bonding material 124 is melted by reflowing or the like so as to connect the electrical connecting member 110 to the electrode 104 of the semiconductor element 102 (FIG. 3B) to FIG. 3C). The wiring pattern connection region 122 is connected to a wiring pattern on a board not illustrated in the drawing by a conductive bonding material.

### [Advantageous Effects of Electrical Connecting Member and Semiconductor Device]

According to the electrical connecting member 110 of the present invention, the plurality of protrusions 112 are formed in the semiconductor connection region 118. As a result, it is possible to prevent the semiconductor element 102 and the electrical connecting member 110 from being connected with each other in an inclined state and hence, a thickness of the conductive bonding material 124 becomes uniform. Further, by applying the conductive bonding material 124 at the positions that correspond to the positions where the plurality of protrusions 112 are formed by coating, it is possible to suppress unnecessary applying of the conductive bonding material 124 by coating. Still further, according to the electrical connecting member 110 of the present invention, the first through hole 114 is formed between two protrusions 112 disposed adjacently to each other and hence, the flow of the melted conductive bonding material 124 is divided. Accordingly, it is possible to easily control the flow of the conductive bonding material 124 and hence, it is possible to prevent wetting and spreading of the conductive bonding material 124 more than necessary. As a result, it is possible to suppress the lowering of reliability of the manufactured semiconductor device and hence, the semiconductor device according to the present invention becomes the semiconductor device where the lowering of the reliability of the semiconductor device is suppressed.

Further, according to the electrical connecting member 110 of the present invention, as described above, it is possible to prevent wetting and spreading of the conductive bonding material 124 more than necessary and hence, there is no possibility that the conductive bonding material 124 spreads to the semiconductor non-connection region 120 and other electrodes 106.

Further, according to the electrical connecting member 110 of the present invention, the conductive bonding material 124 is applied by coating to the position that corresponds to the position where the plurality of protrusions 112 are formed and hence, it is possible to further effectively suppress the lowering of the reliability of the semiconductor device.

Further, according to the electrical connecting member 110 of the present invention, the area (the plane area) of the first through hole 114 is smaller than the area (the plane area) of the protrusion 112 and hence, the parasitic inductance can be lowered accordingly.

According to the electrical connecting member 110 according to the present invention, the protrusion 112 has a conical shape and hence, an amount of conductive bonding material 124 can be increased at a distal end side of the protrusion 112, whereby the conductive bonding material 124 can be positioned around the protrusion 112 uniformly and with certainty. Accordingly, a thickness of the conductive bonding material 124 can be made uniform while ensuring the thickness of the conductive bonding material 124. Further, according to the electrical connecting member 110 of the present invention, the protrusion 112 has a conical shape and hence, the thickness of the conductive bonding material 124 can be made uniform while ensuring the thickness of the conductive bonding material 124 and hence, it is possible to suppress the occurrence of a drawback such as the generation of a crack in the conductive bonding material 124 after the conductive bonding material 124 is hardened.

Further, according to the electrical connecting member 110 of the present invention, the second through hole 116 is formed in the semiconductor non-connection region 120. Accordingly, the conductive bonding material 124 does not become wet or spread more than necessary toward in the direction of the wiring pattern connection region 122 from the semiconductor connection region 118 and hence, there is no possibility that a short-circuit failure is induced between an end surface of the semiconductor element 102 and the electrical connecting member 110.

Further, according to the electrical connecting member 110 of the present invention, the protective insulation layer 108 is formed on the entirety or a part of the region of the electrical connecting member 110 that corresponds to the semiconductor non-connection region 120 of the semiconductor element 102. Accordingly, there is no possibility that the conductive bonding material 124 becomes wet and spreads toward the semiconductor non-connection region 120.

The semiconductor device according to the present invention is the semiconductor device that includes: the semiconductor element 102 having the electrode 104; the wiring pattern (not illustrated in the drawing); and the plate-shaped electrical connecting member 110 that connects the electrode 104 of the semiconductor element 102 and the wiring pattern to each other. Accordingly, the semiconductor device according to the present invention becomes a semiconductor device where the lowering of reliability is suppressed.

The electrical connecting member 110 according to the present invention is a plate-shaped electrical connecting member, and has a larger bonding area than the electrical connecting member such as a wire and hence, the parasitic inductance can be made small. Accordingly, in a case where the electrical connecting member 110 is applied to a semiconductor device that uses a semiconductor element formed of a next-generation power semiconductor (a semiconductor formed using gallium nitride, silicon carbide, or gallium oxide as a material), a particularly large advantageous effect can be acquired. In the embodiment described hereinafter, the electrical connecting member and the semiconductor device of the present invention are described using an electronic module that uses a semiconductor element formed of a next-generation power semiconductor (GaN) is used as such a semiconductor device.

### [Configurational Example of Semiconductor Device]

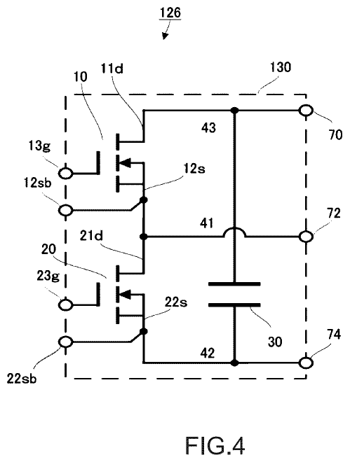

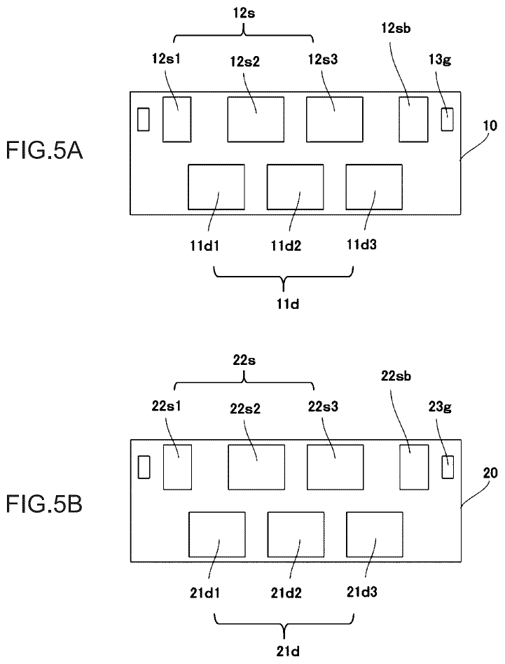

FIG. 4 is a view illustrating an equivalent circuit 126 of the electronic module 130 according to the embodiment. FIG. 5A and FIG. 5B are views illustrating the electrode structure of the semiconductor element (the first semiconductor element 10, the second semiconductor element 20) according to the embodiment. FIG. 5A is a view illustrating the electrode structure of the first semiconductor element 10, and FIG. 5B is a view illustrating the electrode structure of the second semiconductor element 20. FIG. 6 is an enlarged perspective view of a main part of the electronic module 130 according to the embodiment.

As illustrated in FIG. 4, a drain electrode 11d of the first semiconductor element 10 is connected to a power source terminal 70 via a third wiring pattern 43. A source electrode 12s of the first semiconductor element 10 is connected to a drain electrode 21d of the second semiconductor element 20 and a first wiring pattern 41, and is connected to an output terminal 72 via a first wiring pattern 41. A source electrode 22s of the second semiconductor element 20 is connected to a ground terminal 74 via a second wiring pattern 42. A capacitor 30 is connected to the power source terminal 70 and the ground terminal 74 via the third wiring pattern 43 and the second wiring pattern 42. A circuit is established where the first semiconductor element 10 and the second semiconductor element 20 are connected to each other in series, and the capacitor 30 is connected in parallel to the first semiconductor element 10 and the second semiconductor element 20. The electronic module 130 according to the embodiment also includes a detection-use source electrode 12sb and a detection-use source electrode 22sb.

Both the first semiconductor element 10 and the second semiconductor element 20 are formed of an MOS transistor. As illustrated in FIG. 5A and FIG. 5B, the first drain electrode 11d and the second drain electrode 21d are disposed on one side of the same surface of each of the first semiconductor element 10 or the second semiconductor element 20, and a first source electrode 12s, a second source electrode 22s are disposed on the other side of the same surface of each of the first semiconductor element 10 or the second semiconductor element 20. As illustrated in FIG. 5A, the first drain electrode 11d is constituted of three individual electrodes 11d1, 11d2, 11d3. As illustrated in FIG. 5B, the second drain electrode 21d is constituted of three individual electrodes 21d1,21d2, 21d3. Further, as illustrated in FIG. 5A, the first source electrode 12s is constituted of three individual electrode 12s1, 12s2, 12s3. As illustrated in FIG. 5B, the source electrode 22s is constituted of three individual electrodes 22s1, 22s2, 22s3. In FIG. 5A, symbol 13g indicates a first gate electrode, and symbol 12sb indicates a first detection-use source electrode. Further, in FIG. 5B, symbol 23g indicates a second gate electrode, and symbol 22sb indicates a second detection-use source electrode.

In the electric module 130 according to the embodiment, as illustrated in FIG. 6, the electrical connecting member 110 is connected with the semiconductor element in a state where the protrusion 112 is disposed at the positions of the drain electrodes 21d1, 21d2, 21d3, or the respective protrusions 112 are disposed at the positions of the source electrodes 12s1, 12s2, 12s3.

The electric module 130 according to the embodiment is a resin sealed type electronic module. As illustrated in FIG. 6, the electronic module 130 includes: a board 40 on which the first wiring pattern 41, the second wiring pattern 42 and the third wiring pattern 43 are formed; the first semiconductor element 10 on which the plurality of the first electrodes (the first drain electrode 11d, the first source electrode 12s, the first detection-use source electrode 12sb, the first gate electrode 13g) are formed; the second semiconductor element 20 on which the plurality of second electrodes (the second drain electrode 21d, the second source electrode 22s, the second detection—use source electrode 22sb, the second gate electrode 23g) are formed; and the capacitor 30.

The first semiconductor element 10 is mounted on the first wiring pattern 41, the first source electrode 12s is connected to the first wiring pattern 41 via a first electrical connecting member 51, and the second drain electrode 21d is connected to the first wiring pattern 41 via a fourth electrical connecting member 54. The second semiconductor element 20 is mounted on the second wiring pattern 42, the second source electrode 22s is connected to the second wiring pattern 42 via the second electrical connecting member 52, and one portion 31 of the capacitor 30 is connected to the second wiring pattern 42. The first drain electrode 11d is connected to the third wiring pattern 43 via a third electrical connecting member 53, and the other portion 32 of the capacitor 30 is connected to the third wiring pattern 43. The board 40 is, for example, a DCB board where a copper circuit board is directly bonded to a ceramic board.

In the electronic module 130 according to the embodiment, as illustrated in FIG. 6, the second electrical connecting member 52 and the third electrical connecting member 53 are formed using a wire-like electrical connecting member. However, the first electrical connecting member 51 and the fourth electrical connecting member 54 are formed using an electrical connecting member having a plate shape (the electrical connecting member 110 of the present invention).

As illustrated in FIG. 6, the electrical connecting member 110 that constitutes the first electrical connecting member 51 connects, with a width that covers three first source electrodes 12s (12s1, 12s2, 12s3), the first source electrodes 12s (12s1, 12s2, 12s3) and the first wiring pattern 41 to each other. The electrical connecting member 110 that constitutes the fourth electrical connecting member 54 connects, with a width that covers three second drain electrodes 21d (21d1, 21d2, 21d3), the second drain electrodes 21d (21d1, 21d2, 21d3) and the first wiring pattern 41 to each other.

As these first electrical connecting member 51 and the fourth electrical connecting member 54, the electrical connecting member 110 of the present invention is used. That is, the electrical connecting member 110 includes the semiconductor connection region 118, the semiconductor non-connection region 120, and the wiring pattern connection region 122, wherein the plurality of protrusions 112 are formed in the semiconductor connection region 118, and the first through hole 114 is formed between two protrusions disposed adjacently to each other out of the plurality of protrusions 112 (see FIG. 1).

As has been described above, according to the electronic module 130 according to the embodiment (corresponding to the semiconductor device of the present invention), the electrical connecting member 110 of the present invention is used as the first electrical connecting member 51 and a fourth electrical connecting member 54. Accordingly, it is possible to prevent the respective semiconductor elements (the first semiconductor element 10, the second semiconductor 20) and the respective electrical connecting members (the first electrical connecting member 51, the fourth electrical connecting member 54) are bonded to each other in a state where the respective semiconductor elements and the respective electrical connecting members are inclined and hence, a thickness of the conductive bonding material becomes uniform. Further, the conductive bonding material is applied by coating to the positions that correspond to the positions where the plurality of protrusions are formed and hence, applying of an unnecessary conductive bonding material by coating can be suppressed. Further, the first through hole is formed between two protrusions disposed adjacently to each other and hence, the flow of the melted conductive bonding material is separated and hence, it is possible to easily control the flow of the conductive bonding material and hence, it is possible to prevent the wetting and the spreading of the conductive bonding material more than necessary. As a result, the electronic module 130 according to the embodiment (corresponding to the semiconductor device of the present invention) becomes a semiconductor device where the lowering of reliability is suppressed.

Although the embodiment of the present invention has been described heretofore, the present invention is not limited to the embodiment described above, and various modifications and applications are conceivable without departing from the gist of the present invention.

(1) FIG. 7 is an enlarged perspective view of a main part of an electronic module 132 according to a modification 1. As illustrated in FIG. 7, the electronic module 132 according to the modification 1 differs from the electronic module 130 according to the embodiment with respect to a point that, in place of the wire-like second electrical connecting member 52 and the wire-like third electrical connecting member 53, a second electrical connecting member 52 having a plate shape and a third electrical connecting member 53 having a plate shape (that is, the electrical connecting member 110 of the present invention) are used. The electronic module having such a structure (the electronic module 132), also can directly acquire the advantageous effects that the semiconductor device of the present invention possesses.

(2) In the above-mentioned embodiment, the electrical connecting member of the present invention has been described using the semiconductor element that includes the plurality of individual drain electrodes and the plurality of individual source electrodes on one surface thereof. However, the present invention is not limited to such a configuration. The present invention is also applicable to a semiconductor element that has, as drain electrodes, drain electrodes having the structure where the individual drain electrodes are partially connected, or a semiconductor element that has, as source electrodes, source electrodes having the structure where the individual source electrodes are partially connected. Further, the present invention is also applicable to a semiconductor element having the structure where drain electrodes and the respective source electrodes are assembled in a complicated manner.

(3) In the above-mentioned embodiment, as the wiring pattern that is connected to the electrodes of the semiconductor element, the wiring pattern that is formed on the board is used. However, the present invention is not limited to such a configuration. The present invention can also use wiring patterns other than the wiring pattern formed on the board (for example, a lead frame, a bulk-like wiring pattern and the like).

(4) In the above-mentioned embodiment, the semiconductor device has been described using the half bridge circuit. However, the present invention is not limited to such a configuration. The present invention is also applicable to a totem-pole-type power factor improving circuit and other circuits.

1. An electrical connecting member having a plate shape that is used for connecting an electrode of a semiconductor element having the electrode and a wiring pattern to each other, the electrical connecting member comprising:
a semiconductor connection region that is connected to the electrode of the semiconductor element via a conductive bonding material;
a semiconductor non-connection region that is not connected to the electrode of the semiconductor element; and
a wiring pattern connection region that is connected to the wiring pattern, wherein
a plurality of protrusions are formed in the semiconductor connection region, and a first through hole is formed between two protrusions disposed adjacently to each other out of the plurality of protrusions.

2. The electrical connecting member according to claim 1, wherein
the semiconductor element is a semiconductor element that has a plurality of electrodes on one surface thereof, and
the electrical connecting member is used for connecting the plurality of electrodes and the wiring pattern to each other.

3. The electrical connecting member according to claim 1, wherein
the semiconductor element is a semiconductor element that has plural kinds of electrodes on one surface thereof, and
the electrical connecting member is used for connecting one kind of electrode out of the plural kinds of electrodes and the wiring pattern to each other.

4. The electrical connecting member according to claim 3, wherein
the one kind of electrode is divided into a plurality of individual electrodes, and
the plurality of respective protrusions are formed in regions of the plurality of respective individual electrodes that correspond to the plurality of respective individual protrusions.

5. The electrical connecting member according to claim 1, wherein
an area (a plane area) of the first through hole is smaller than an area (a plane area) of the protrusion.

6. The electrical connecting member according to claim 1, wherein
the protrusion has a conical shape, a pyramidal shape, a circular columnar shape, a prismatic shape or a semispherical shape.

7. The electrical connecting member according to claim 1, wherein a second through hole is formed in the semiconductor non-connection region.

8. A semiconductor device comprising:
a semiconductor element that has an electrode;
a wiring pattern; and
an electrical connecting member having a plate shape that connects the electrode of the semiconductor element and the wiring pattern, wherein
the electrical connecting member is the electrical connecting member according to claim 1.
